(19) United States
(12) Patent Application Publication
(10) Pub. No.: US 2009/0261851 A1
(43) Pub. Date: Oct. 22, 2009

(54) SPRING PROBE

(75) Inventors: Jiachun Zhou, Gilbert, AZ (US); Praveen Matlapudi, Chandler, AZ (US)

Correspondence Address: PEPPER HAMILTON LLP, ONE MELLON CENTER, 50TH FLOOR, 500 GRANT STREET, PITTSBURGH, PA, 15219, US

(73) Assignee: ANTARES ADVANCED TEST TECHNOLOGIES, INC., Vancouver, WA (US)

(21) Appl. No.: 12/105,922

(22) Filed: Apr. 18, 2008

(51) Int. Cl. G01R 1/067; H01R 43/16

(52) U.S. Cl. 324/757; 29/874

(57) ABSTRACT

According to some example embodiments, an interconnect has a crown with contact tips, in which each of the contact tips is structured to physically contact a substantially spherical solder ball along a curved inner surface of the contact tip.

### BACKGROUND

1. Technical Field

This disclosure relates generally to electrical interconnectors and, more particularly, to electrical interconnectors with improved crown structures for connecting to solder balls, such as solder balls in a Ball Grid Array (BGA) Integrated Circuit (IC) package.

2. Description of the Related Art

All IC packages must be tested during or after the production process to verify electrical performance. Interconnectors are frequently used in the testing process. For purposes of this disclosure, an interconnector is defined as a mechanical assembly for electrically connecting two electrical components in a temporary fashion. In a test scenario, an interconnector may be used to electrically connect a Device Under Test (DUT), such as an IC chip, to a test circuit board. For example, spring probes, which are one type of interconnector, are frequently used during the testing of BGA IC packages to electrically connect individual solder balls of the BGA package to a corresponding pad on a test circuit board.

FIG. 1 is a perspective diagram that illustrates a conventional spring probe 100. The top side of the spring probe 100 includes a crown 110, which is designed to hold a corresponding solder ball from, for example, a BGA package. The bottom of the spring probe 100 is designed to contact an electrical pad or land on the circuit board. Thus, the spring probe 100 can electrically connect the solder ball of the BGA package to the pad on the circuit board.

FIG. 2 is a perspective diagram that further illustrates the crown 110 of the conventional spring probe 100. FIG. 3 is a perspective diagram that illustrates the crown 110 in contact with a solder ball 300 from, for example, a BGA package. Referring to FIG. 2, the crown 110 includes cutting tips 210 and cutting edges 220, which are arranged to contact the solder ball 300, as shown in FIG. 3. There exists a point contact between the cutting tips 210 and the solder ball 300, and straight line contact between the cutting edges 220 and the solder ball.

The solder ball 300 is typically made of an alloy such as Pb—Sn or Sn—Ag—Cu that has a relatively low melting point, in the range of 150 to 250 degrees Celsius (C). Unfortunately, these alloys are also mechanically soft and when the solder ball 300 is compressed against a conventional crown, such as crown 110, small particles may be removed from the solder ball. These small particles, referred to as contaminates, may seriously affect the quality of the electrical contact between the crown 110 and the solder ball 300. The conventional crown 110 does not provide a reliable contact due to the limited contact area between the crown and the solder ball and also due to the production of contaminants.

Lately, with the development of Pb-free solder balls and the increasing power found in IC chips, there has been a need for better electrical contact between the solder balls and the interconnect crowns. Various efforts have been made to improve the electrical contact, such as the use of different plating metals on the crown or providing self-cleaning crowns. To date, none of these efforts have been largely successful in solving the Pb-free solder ball contact problem described above.

### BRIEF DESCRIPTION OF THE DRAWINGS

The drawings that are briefly described below, some of which are illustrative of example embodiments, are to be used in conjunction with the detailed description so that those of skill in the art will have a complete and thorough understanding of the inventive principles. The drawings are not drawn to scale, and some features in the drawings may be exaggerated relative to other features in order to more clearly illustrate the example embodiments.

FIG. 1 is a perspective diagram that illustrates a conventional spring probe.

FIG. 2 is a perspective diagram that further illustrates the crown of the conventional spring probe of FIG. 1.

FIG. 3 is a perspective diagram that illustrates the crown of the conventional spring probe of FIG. 1 in contact with a conventional solder ball from, for example, a BGA package.

FIG. 4 is a perspective diagram that illustrates a crown of an improved interconnect according to an example embodiment.

FIG. 5 is a perspective diagram that illustrates a crown of an improved interconnect according to another example embodiment.

FIG. 6 is a perspective diagram that illustrates a crown of an improved interconnect according to another example embodiment.

FIG. 7 is a perspective diagram that illustrates a crown of an improved interconnect according to another example embodiment.

FIG. 8 is a perspective diagram that illustrates the crown of FIG. 4 contacting a solder ball from, for example, a BGA IC package.

FIGS. 9-13 are perspective diagrams illustrating some processes included in a method of manufacturing the crown of FIG. 4 according to an example embodiment.

FIG. 14 is a perspective diagram that illustrates a crown of an improved interconnect according to another example embodiment.

### DETAILED DESCRIPTION OF EXAMPLE EMBODIMENTS

The example embodiments that are described below in conjunction with the drawings are to be taken as illustrative of, rather than limiting to, the inventive principles that may be found in one or more of the example embodiments.

Example embodiments may advantageously mitigate one or more of the problems associated with conventional crown structures, some of which were described above. Example embodiments may accomplish this by providing an improved crown structure that exhibits curved contact surfaces where the solder ball meets the crown and that prevents contaminants from collecting inside the crown.

FIG. 4 is a perspective diagram that illustrates a crown 400 of an interconnect according to an example embodiment. FIG. 8 is a perspective diagram that illustrates the crown 400 of FIG. 4 contacting a solder ball 800 from, for example, a BGA IC package. Referring to FIGS. 4 and 8, the crown 400 includes four contact tips 410. According to other embodiments, there may be more or less than four contact tips 410. There may also be an even or odd number of contact tips 410 across different embodiments, although for some manufacturing processes (such as machining) it is easier to have an even number of contact tips.

Some of the structural features of the contact tips 410 include the contact tip edges 420 that are disposed at the uppermost, or distal ends of the contact tips. The contact tips 410 further include contact surfaces 430, which are the radially inward facing surfaces of the contact tips.

In this embodiment, the contact surfaces 430 are characterized in that the intersection of each of the contact surfaces with a plane that is perpendicular to an axis running lengthwise through the interconnect form arc segments of a common circle. This characterization applies to the contact tip edges 420 as well.

Each of the contact tips 410 is separated from an adjacent contact tip by a cut 440, which in this embodiment is shaped substantially like the letter “V,” although other shapes could be used. For example, in alternative embodiments the cuts could be shaped substantially like the letter “U,” with a rounded bottom, or the cuts could be shaped substantially like the letter “U,” but with a flat bottom. The cuts 440 are advantageous in that they provide a channel that allows contaminants to migrate outwards from the central region of the crown 400, which prevents the unwanted buildup of contaminants within the region inside the contact surfaces 430.

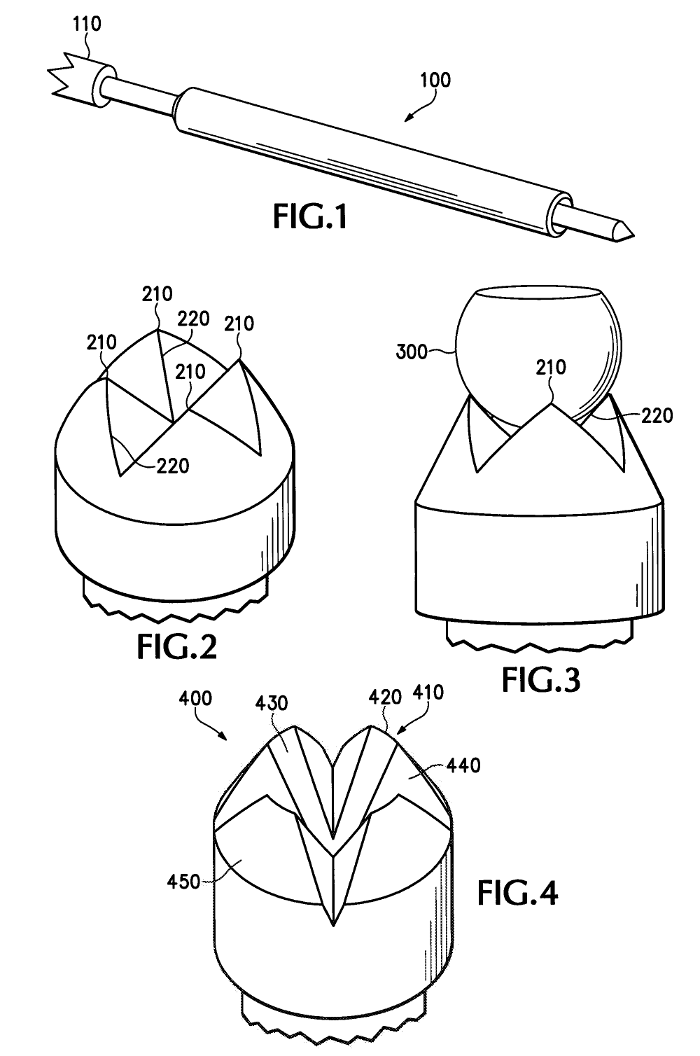

The curved shapes of the contact surfaces 430 and the contact tip edges 420 are advantageous as well, as it provides for more contact points with a substantially spherical solder ball (not shown) compared to the conventional crown 110 that is illustrated in FIGS. 1, 2, and 3. For example, the cutting tips 210 of the conventional crown 110 form a point-contact with the solder ball 300, whereas the curved contact tip edges provide a curved-line contact with the solder ball. Similarly, the cutting edges 220 of the conventional crown 110 form straight-line contacts with the solder ball 300, whereas the contact surfaces 430 also provides for curved-line contact with the solder ball 800.

A straight-line contact is preferred over a point-contact, and a curved-line contact is preferred over a straight-line contact, as simple geometry dictates that there are more points along a straight line than a single point, and further that there are more points along a curved line than there are along a straight one. Thus, according to this and the other example embodiments illustrated, the contact points between the solder ball 800 and the crown 400 are increased relative to the conventional crown 110 and the solder ball 300, improving the quality of the electrical connection. Additionally, although the diameter of a solder ball 800 on a BGA package may have variations, the curved contact tip edges 420 as well as the curved and angled contact surfaces 430 ensure that the crown 400 can match one diameter of the solder ball 800.

The contact tips 410 further include outer surfaces 450, which are the radially outward facing surfaces of the contact tips. The angle at which the outer surfaces 450 meet the contact surfaces 430 at the contact tip edges 420 are less than 90 degrees, and in more preferred embodiments, less than about 45 degrees. Thus, the contact tip edges 420 may have a relatively sharp chisel point, or, since they are curved, a shovel point that can easily penetrate the solder ball 300. This also improves the quality of the electrical contact between the crown 400 and solder ball 300.

The remaining example embodiments described in this disclosure share the features that were described above with respect to the crown 400 illustrated in FIG. 4. Thus, the features of the remaining embodiments may be described in less detail because it is assumed that those of ordinary skill will easily recognize and readily appreciate the features that are shared across the various described embodiments.

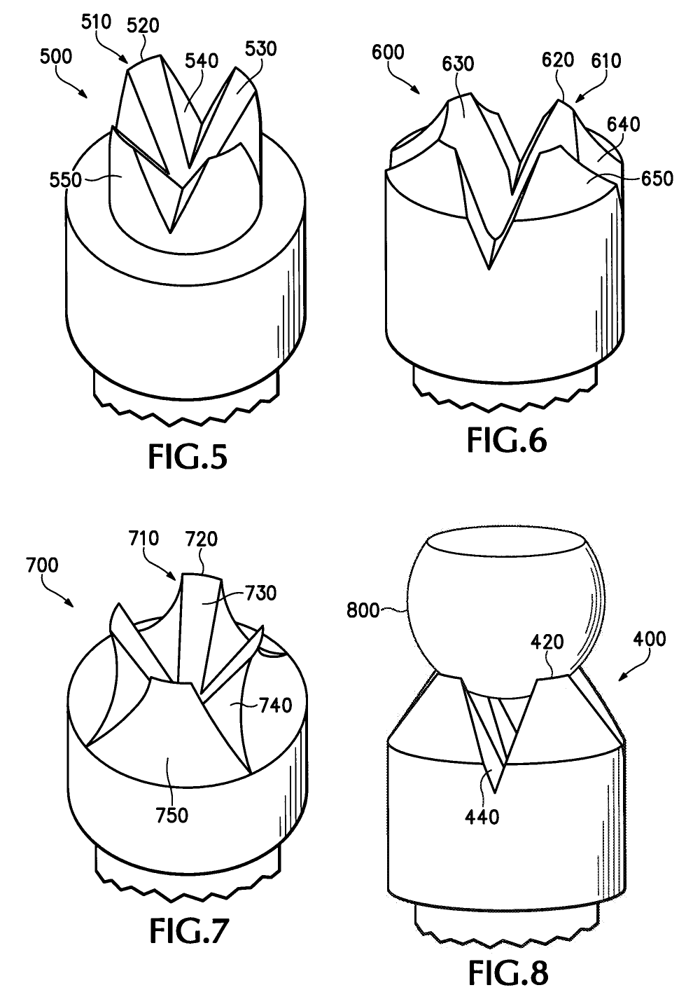

FIG. 5 is a perspective diagram that illustrates a crown 500 of an interconnect according to another example embodiment. Like crown 400, crown 500 has contact tips 510, which include contact tip edges 520, contact surfaces 530, cuts 540, and outer surfaces 550. The overall shape of the crown 500, however, is slightly different from the crown 400 because a radially outer portion of the crown has been removed.

FIG. 6 is a perspective diagram that illustrates a crown 600 of an interconnect according to another example embodiment. Like crowns 400 and 500, crown 600 has contact tips 610, which include contact tip edges 620, contact surfaces 630, cuts 640, and outer surfaces 650. Unlike crowns 400 and 500, crown 600 additionally has a cup surface 660, which is disposed in the center of the crown, beneath the contact surfaces 630.

Like the other contact surfaces 430, 530, and 630, the cup surface 660 is characterized in that the intersection of the cup surface with a plane that is perpendicular to an axis running lengthwise through the interconnect form arc segments of a common circle. However, the angle at which the cup surface 660 approaches the center of the common circle is not as steep as the angle at which the contact surfaces 630 approach the center of the common circle. This increases the volume of the region within the crown 600, allowing the crown to collect more contaminants before the contaminants begin to adversely effect the quality of the contact between the contact surfaces 630 and the solder ball 800.

FIG. 7 is a perspective diagram that illustrates a crown 700 of an interconnect according to another example embodiment. Like crowns 400, 500, and 600, crown 700 has contact tips 710, which include contact tip edges 720, contact surfaces 730, cuts 740, and outer surfaces 750. Unlike some of the other illustrated embodiments, which show that the outer surfaces 450 and 650 are closest to the center of the crowns 450, 650 at the contact tip edges 420, 720, respectively, the outer surface 750 has a profile where it is closer to the center of the crown 700 at some point below the contact tip edges 720. This allows for an extreme acute angle at the contact tip edge 720, making the contact tip edges relatively sharp, and improving the ease by which the contact tip edges can penetrate the solder ball 800. As was explained above for a different embodiment, increasing the sharpness of the contact tip edges 720 may also improve the quality of the electrical connection between the crown 700 and solder ball 800.

FIG. 14 is a perspective diagram that illustrates a crown 1400 of an interconnect according to another example embodiment. Like crowns 400, 500, 600, and 700, crown 1400 has contact tips 1410, which include contact tip edges 1420, contact surfaces 1430, cuts 1440, and outer surfaces 1450. Crown 1400 is similar to crown 400 of FIG. 4, but the cuts 1440 are larger and angled such that the contact tip edges 1420 are more pointed and the contact surfaces 1430 are smaller relative to those of the crown 400. Thus, the contact tip edges 1420 are sharper, which may improve the quality of the electrical connection between the crown 1400 and solder ball 800.

Example embodiments also include methods of manufacturing crowns for interconnectors that exhibit one or more of the structural features described above. In the industry, material is typically removed from a blank using a machining process to obtain the conventional crown designs. Machining is also a suitable method for obtaining example embodiments that exhibit the structural features described above. However, other methods, such as molding or die-casting, might also be used. The machining process is typically preferred because the tolerances that can be achieved are usually greater than with other conventional processes.

According to some example embodiments, a method of manufacturing a crown of an interconnect includes forming contact tips that are arranged in a circular configuration around a central axis running lengthwise through the interconnect. According to the example embodiments, the contact tips are formed to have curved surfaces in which the curved surfaces are characterized in that intersections of the curved surfaces with a plane that is perpendicular to the central axis form arc segments of a circle.

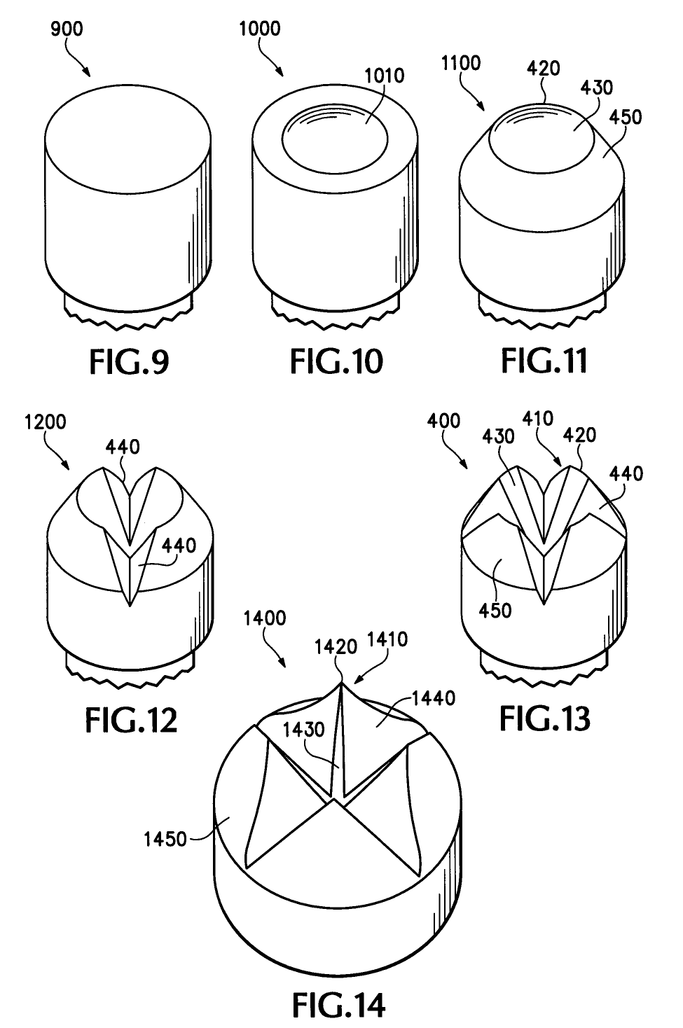

FIGS. 9-13 are perspective diagrams illustrating some machining processes included in a method of manufacturing the crown 400 according to an example embodiment. Those of ordinary skill will understand that while the machining processes that are illustrated in FIGS. 9-13 show a particular sequence to the machining processes, the order that is illustrated and described does not necessarily mean that the particular illustrated processes are required to exhibit the same order among all example embodiments. Rather, it should be appreciated that in other example embodiments, the sequence of the processes could be different than the particular order shown in FIGS. 9-13.

In the following description, many common verbs such as drilling, cutting, shaving, removing, tooling, lathing, etc., may be used to describe a particular machining process. In some cases the particular machine tool associated with the described process is self-explanatory. For example, a drill-bit is typically associated with drilling. In other cases, however, there may be several machining tools that can be used to perform the particular process that is described. For purposes of this disclosure, it will be assumed that the skilled machinist would be able to select one or more appropriate machine tools from among the wide variety of machine tools that are available in order to perform the described task. Thus, this disclosure will not attempt to describe the numerous techniques and machine tools that are common to the machinist's trade.

FIG. 9 illustrates a cylindrical blank 900, which represents a starting point prior to beginning the machining processes that achieve the crown 400. FIG. 10 illustrates a structure 1000, which is obtained by drilling a substantially cone-shaped hole 1010 into the top of the cylindrical blank 900 of FIG. 9. As will be understood by those of ordinary skill, the shape of the drill bit and the depth to which the cylindrical blank 900 is drilled substantially determines the size and shape of the cone-shaped hole 1010. Next, as shown in FIG. 11, a structure 1100 is achieved by cutting away a top portion of the structure 1000 around the perimeter of the cone-shaped hole 1010 at a predetermined angle. At this point in the machining process, the curved contact surfaces 430, the outer surfaces 450, and the curved contact tip edges 420 of the contact tips 410 (see FIG. 4) are substantially formed. In alternative embodiments, the sequence of the processes illustrated in FIGS. 10 and 11 may be reversed.

Next, as illustrated in FIG. 12, a structure 1200 is achieved by making two substantially V-shaped cuts 440 into the structure 1100 of FIG. 11. As shown, the V-shaped cuts 440 are aligned along the same axis so the cutting tool used to make the cuts can make one pass along the top of structure 1100 and remove material from both of the cuts. The depth and angle of the V-shaped cuts 440 is largely a matter of design trade-offs, as those of ordinary skill will appreciate that while large cuts make it easier for contaminants to exit the crown, they also necessarily result in smaller contact surfaces 430 and smaller contact tip edges 420, which can reduce the quality of the resulting contact between the crown 400 and a solder ball.

Finally, as shown in FIG. 13, the crown 400 is achieved by making another two substantially V-shaped cuts 440 into the structure 1200 of FIG. 12, at an angle that is normal to the alignment of the first two V-shaped cuts 440. In this embodiment, there are an even number (four) of V-shaped cuts 440 of substantially the same size and shape, which makes the crown 400 easier and cheaper to manufacture relative to embodiments where the cuts are not of the same size and shape, and also results in an even number (four) of contact tips 410 with contact tip edges 420 that are uniformly spaced around the circumference of a circle. However, in alternative embodiments the cuts may not be of the same size and shape, and there may also be an odd number of contact tips.

Although the above-described machining processes were specific to the example embodiment illustrated in FIG. 4, it should be apparent to those of ordinary skill how similar or slightly modified processes may be used to achieve the example embodiments illustrated in FIGS. 5-7. The example embodiments described above are illustrative rather than limiting of the inventive principles, with the attached claims defining the metes and bounds of the inventive principles.

1. An interconnect having a crown disposed at an end of the interconnect, the crown structured to physically contact a substantially spherical solder ball, the crown comprising:
contact tips disposed at a distal end of the crown, the contact tips structured such that uppermost edges of the contact tips are substantially coplanar and constitute arcs of a common circle; and
contact surfaces on the contact tips that are curved, the contact tips structured such that lines drawn normal to points on the contact surfaces intersect an axis that is normal to a center of the common circle.

2. The interconnect of claim 1, the contact tips structured such that the lines drawn normal to points on the contact surfaces intersect the axis at an angle that is less than ninety degrees.

3. The interconnect of claim 2, the contact tips structured such that the points on the contact surfaces also constitute points on a surface of a cone.

4. The interconnect of claim 1, the crown further comprising outer surfaces on the contact tips, the outer surfaces facing radially outwards from the axis, the contact tips structured such that an angle between a corresponding contact surface and a corresponding outer surface at a corresponding uppermost edge of the contact tip is less than ninety degrees.

5. The interconnect of claim 4, the crown further comprising V-shaped cuts that separate adjacent contact tips, the V-shaped cuts providing a channel to remove contaminants that are produced from contact between the crown and the substantially spherical solder ball.

6. The interconnect of claim 1, the contact tips structured such that the uppermost edges of the contact tips are distributed around a circumference of the common circle at a uniform interval.

7. The interconnect of claim 6, the contact tips structured such that each of the contact tips is substantially equal in size and shape.

8. An interconnect having a crown with contact tips, each of the contact tips structured to physically contact a substantially spherical solder ball along a curved inner surface of the contact tip.

9. The interconnect of claim 8, in which each of the contact tips is structured such that an intersection between the curved inner surface and a plane that is normal to an axis that is parallel to a longest dimension of the interconnect forms an arc that is equidistant from the axis along substantially an entire length of the arc.

10. The interconnect of claim 9, the contact tips further comprising curved outer surfaces, the contact tips structured such that an angle between a corresponding curved inner surface and a corresponding curved outer surface and having a vertex disposed at a distal end of the corresponding contact tip is less than about forty-five degrees.

11. The interconnect of claim 10, the contact tips structured such that a portion of the curved inner surfaces approaches closer to the axis as a distance from the distal end of the contact tips increases.

12. The interconnect of claim 11, the contact tips structured such that another portion of the curved inner surfaces remains substantially equidistant from the axis as a distance from the distal end of the contact tips increases.

13. The interconnect of claim 11, the contact tips structured such that another portion of the curved inner surfaces approaches closer to the axis as a distance from the distal end of the contact tips increases, the another portion approaching the axis at a first rate, the portion approaching the axis at a second rate, the first rate and the second rate different from one another.

14. The interconnect of claim 11, the contact tips structured such that each of the contact tips is separated by a V-shaped cut in the crown, the V-shaped cuts structured to allow contaminants that are produced from contact between the crown and the substantially spherical solder ball to be removed from the crown.

15. A method of manufacturing a crown of an interconnect, the method comprising forming contact tips that are arranged in a circular configuration around a central axis running lengthwise through the interconnect, the contact tips having curved surfaces, the curved surfaces characterized in that intersections of the curved surfaces with a plane that is perpendicular to the central axis form arc segments of a circle.

16. The method of claim 15, wherein forming the contact tips comprises:
drilling a hole in an upper surface of a blank; and
making at least one substantially V-shaped cut across the upper surface of the blank.

17. The method of claim 16, wherein drilling the hole comprises drilling the hole such that at least a portion of the curved surfaces are angled towards the central axis as a depth of the hole increases.

18. The method of claim 16, wherein drilling the hole comprises drilling the hole such that an inverted cone placed within the hole would contact substantially all of the curved surfaces.

19. The method of claim 16, wherein making the at least one substantially V-shaped cut comprises making a depth of the substantially V-shaped cut at least as deep as a depth of the hole.

20. The method of claim 15, wherein making the at least one substantially V-shaped cut comprises making the at least one V-shaped cut such that distal ends of the contact tips form arc segments of the circle, in which the distal ends of the contact tips are uniformly spaced around the circle.
